(19) United States
(12) Patent Application Publication
(10) Pub. No.: US 2013/0068302 A1
(43) Pub. Date: Mar. 21, 2013

(54) APPARATUS FOR SOLAR TRACKING OF ENERGY HARVESTER

(71) Applicants: A.S.M. Muker-Uz-Zaman, Kuala Lumpur (MY); Masuri Othman, Kuala Lumpur (MY); Muhamad Alias Dzuzlindah, Kuala Lumpur (MY); Mohammad Shaharia Bhuyan, Kuala Lumpur (MY); Khairul Hakimin Zainuddin, Kuala Lumpur (MY); Abdul Ghani Othman, Kuala Lumpur (MY)

(72) Inventors: A.S.M. Muker-Uz-Zaman, Kuala Lumpur (MY); Masuri Othman, Kuala Lumpur (MY); Muhamad Alias Dzuzlindah, Kuala Lumpur (MY); Mohammad Shaharia Bhuyan, Kuala Lumpur (MY); Khairul Hakimin Zainuddin, Kuala Lumpur (MY); Abdul Ghani Othman, Kuala Lumpur (MY)

(21) Appl. No.: 13/119,864

(22) PCT Filed: Sep. 17, 2009
(86) PCT No.: PCT/MY09/00150

§ 371 Date: Nov. 5, 2012

(30) Foreign Application Priority Data
Sep. 18, 2008 (MY) PI 200883638

(51) Int. Cl. H01L 31/0232

(52) U.S. Cl. CPC H01L 31/02325
USPC 136/259

(57) ABSTRACT

An apparatus for solar tracking using minimal energy is described. A prismatic energy harvester (10) is positioned above a spring (20). The harvester has a pair of ears (14) at both side of the top portion of the harvester. The ear is moved by strings (16) from a reel (18) connected to a box of motor (12). At least two photo-resistive elements track the sun rays intensity to identify the position of the sun. Then, the motor adjust the reels to rotate the harvester using strings until the harvester and the sun is at right angle. The photo-resistive elements continuously track the sun so that the harvester can be rotated towards the sun at right angle.

The present invention relates generally to apparatus for energy harvesting, more particularly to apparatus for solar energy harvesting with solar tracker.

### BACKGROUND TO THE INVENTION

For profiling environment in precision agriculture using wireless sensor network, a huge number of low powered devices are required. It is desirable that that these devices harvest their own power using autonomous energy harvester. Solar cell, utilizing solar energy becomes an attractive viable source to complement energy harvester.

The amount of energy harvested form solar cell is dependant on the angle of solar ray induced on the cell. Optimum solar energy is harvested when the solar ray and solar cell are at right angle. However, the sun changes its position all day. As the sun changes its position, the angle of solar ray changes and the solar ray induced on the cell will affect the energy harvested. Therefore, a mechanism is required to change the angle of the solar cell so that it can optimize energy harvesting.

A sun tracker, usually has at least two photo-resistive elements to sense and compare light intensity on a surface of solar cell. If a difference is detected, a motor will adjust the surface of the solar cell to an angle which will produce minimal difference. When there is minimal difference, the incident light received by both photo-resistive elements is parallel. Early sun tracker uses a motor to adjust the solar cell to rotate in a single field.

Another attempt uses multiple sensors and at least two motors to rotate the solar cell in altitude sensor field and azimuth sensor field. The setup requires complex control to obtain an optimum field of view.

The sun may be obscured by clouds. Another embodiment describes a reflective surface on the photo-resistive element to track the sun when the clouds no longer obscure it.

An efficient way of tracking the sun is desirable to optimize energy harvesting of solar energy while minimizing energy waste to rotate the solar cell.

### SUMMARY OF THE INVENTION

The invention is conceived to provide a setup to continuously rotate an energy harvester towards the direction of the sun so that the angle between the sun and solar cell are at right angle.

It is also an objective of the invention to provide the rotation with minimal energy. Motor with reels, having strings controlling the solar cell and a spring to support the harvester are used to rotate the prismatic energy harvester using minimal energy.

### BRIEF DESCRIPTION OF THE DRAWINGS

The invention will now be described in greater detail, by way of an example, with reference to the accompanying drawings, in which:

FIG. 1 illustrates a diagram of a apparatus for solar tracking of a prismatic energy harvester according to the invention; and

FIG. 2A to FIG. 2C illustrate a series of diagram of the rotation of prismatic energy harvester according to the position of the sun.

### DETAILED DESCRIPTION OF THE DRAWINGS

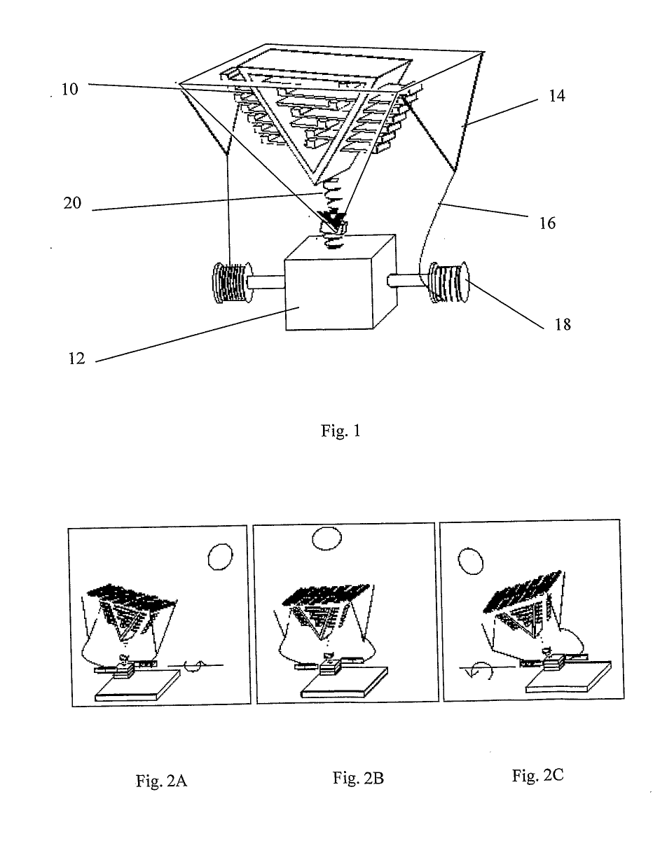

Referring to FIG. 1, there is illustrated an embodiment of a prismatic energy harvester 10 with sun tracker mechanism to rotate the harvester. At least a motor (not shown) is arranged in the box of motor 12. Both side of the top portion of the harvester 10 is clamped with wires which form ears 14, preferably V-shaped ears next to the harvester. A pair of strings 16 from a pair of reels is connected to one end of the ears. The reels 18 are controlled by the box of motor 12.

The prismatic energy harvester 10 is positioned on top of a spring 20. The spring allows the harvester to be floated and required minimal energy to be rotated. Therefore a small rotation of the motor can produce enough power on the string to move the structure according to the position of the sun. find the position of the sun, at least two photo-resistive elements are used to track the intensity of sun ray. The photo-resistive elements will be placed inside the base 12, along with the motor and supporting circuitry.

Referring to FIG. 2A, the photo-resistive elements track the position of the sun to sunrise at east. It sends signal to the motor to rotate the reel so that the ear facing east is lowered while the ear facing west is loosen so that the harvester is tilted and facing directly towards the sun. The photo-resistive elements continuously track the sun so that the harvester can be rotated towards the sun at right angle.

Referring to FIG. 2B, the photo-resistive elements track the position of the sun to sun at noon where it is directly above the harvester. It sends signal to the motor to rotate the reel so that both ears have equal length so that the harvester face towards the sun. The photo-resistive elements continuously track the sun so that the harvester can be rotated towards the sun at right angle.

Referring to FIG. 2C, the photo-resistive elements track the position of the sun to sunset at west. It sends signal to the motor to rotate the reel so that the ear facing west is lowered while the ear facing east is loosen so that the harvester is tilted and facing directly towards the sun. The photo-resistive elements continuously track the sun so that the harvester can be rotated towards the sun at right angle.

Accordingly, the invention has a simple apparatus to continuously track the sun with minimal energy. Although the descriptions above contain many specificities, these should not be construed as limiting the scope of the embodiment but as merely providing illustrations of some of the presently preferred embodiments.

1. An apparatus for solar tracking of energy harvester comprising: a prismatic energy harvester, a spring supporting the harvester, a pair of ears on both side of the top portion of the harvester, a pair of strings connected to one end of the ears, a pair of reels containing strings, a box of motor which controls the reel, and at least two photo-resistive elements to track the intensity of sun ray, wherein the position of the sun is continuously detected by comparing the intensity of sun ray and the motor is directed to adjust the reel so that the harvester is rotated towards the sun at right angle, whereby the spring allows the harvester to be rotated with minimal energy.

2. The apparatus according to claim 1, wherein the pair of ears are preferably V-shaped ears.

3. The apparatus according to claim 2, wherein the pair of V-shaped ears are made with wires.
